(19) United States
(12) Patent Application Publication
(10) Pub. No.: US 2025/0087508 A1
(43) Pub. Date: Mar. 13, 2025

(54) MONITORING DEVICE FOR MEASURING CHARACTERISTICS OF EDGE AREA AND METHOD OF MANUFACTURING THE SAME

(71) Applicants: WIT CORPORATION, Hwaseong-si (KR); FINE SEMITECH CORP., Hwaseong-si (KR)

(72) Inventors: Jae Hwan KIM, Hwaseong-si (KR); Jae Won OH, Gunpo-si (KR)

(21) Appl. No.: 18/963,001

(22) Filed: Nov. 27, 2024

Related U.S. Application Data
(63) Continuation of application No. PCT/KR2022/012655, filed on Aug. 24, 2022.

(30) Foreign Application Priority Data
Jul. 20, 2022 (KR) 10-2022-0089667

(51) Int. Cl. H01L 21/67; G01N 25/72; H01L 21/683

(52) U.S. Cl. CPC H01L 21/67248; G01N 25/72; H01L 21/6831

(57) ABSTRACT

A monitoring device for measuring characteristics of an edge area of an object to be measured and a method of manufacturing the same are disclosed. The monitoring device comprises a lower cover, a guide member disposed on the lower cover, a circuit module in which at least one electrical element is disposed on a circuit board and an upper cover disposed on the guide member or the circuit module. Here, a space is formed at the guide member, and at least partial of the circuit module locates in the space.

### CROSS-REFERENCE TO RELATED APPLICATIONS

This application is a Bypass continuation of pending PCT International Application No. PCT/KR2022/012655, which was filed on Aug. 24, 2022, and which claim priority to Korean Patent Application No. 10-2022-0089667 filed with the Korean Intellectual Property Office on Jul. 20, 2022. The disclosures of the above patent applications are incorporated herein by reference in their entirety.

### TECHNICAL FIELD

The present disclosure relates to a monitoring device for measuring characteristics of an edge area of an object to be measured and a method of manufacturing the same.

### BACKGROUND ART

An electrostatic chuck is a core part in a semiconductor equipment. The temperature of the electrostatic chuck rises and falls at every process, and the temperature of the electrostatic chuck may not be uniform according as resistance of an internal heating electrode changes.

A change of a slope of the electrostatic chuck occurred while the electrostatic chuck is exchanged affects to a plasma distribution. Additionally, a change of an electrical factor of an internal electrode in the electrostatic chuck affects to electrostatic force, and vibration of the semiconductor equipment affects to process performance.

Wafer fault occurs if a semiconductor process or a display process, e.g. an etching process is performed while the electrostatic chuck has undesired temperature or temperature distribution, the semiconductor equipment vibrates or the electrostatic chuck is abnormally tilted. As a result, every wafer may be discarded.

A monitoring device for measuring characteristics of the electrostatic chuck has developed as shown in FIG. 1. The monitoring device has a structure that a sensor, etc. is disposed in an internal space of a wafer 100. It is impossible to measure characteristics of an edge area of the electrostatic chuck using a sensor due to a side of the wafer 100.

### SUMMARY

The present disclosure is to provide a monitoring device for measuring characteristics of an edge area of an object to be measured and a method of manufacturing the same.

A monitoring device according to one embodiment of the present disclosure includes a lower cover; a guide member disposed on the lower cover; a circuit module in which at least one electrical element is disposed on a circuit board; and an upper cover disposed on the guide member or the circuit module. Here, a space is formed at the guide member, and at least partial of the circuit module locates in the space.

A monitoring device according to another embodiment of the present disclosure includes a lower cover; a circuit module disposed on the lower cover; elements disposed on the circuit module; and an upper cover disposed on the elements. Here, wherein the elements include a first element with relatively low height and a second element with relatively great height, a filler is filled on the first element, and a height of the first element on which the filler is filled is identical to a height of the second element.

A monitoring device according to still another embodiment of the present disclosure includes a lower cover; a circuit module disposed on the lower cover; at least one electrical element disposed on the circuit module; and an upper cover disposed on the electrical element. Here, a sensor as the electrical element is disposed on an area of the circuit module corresponding to an extreme edge area of a wafer to be used in following process.

A method of manufacturing a monitoring device according to one embodiment of the present disclosure includes disposing a circuit board on a lower cover; forming a first element with relatively low height and a second element with relatively great height on the circuit board; filling a filler on the first element, thereby making the first element on which the filler is filled to have the same height as the second element; and disposing an upper cover on the first element and the second element.

In a monitoring device and a method of manufacturing the same according to the present disclosure, a sensor is disposed in an area corresponding to an extreme edge area of a wafer to be used in following process. Accordingly, the monitoring device may measure characteristics of an edge area of an object to be measured.

### BRIEF DESCRIPTION OF DRAWINGS

Example embodiments of the present disclosure will become more apparent by describing in detail example embodiments of the present disclosure with reference to the accompanying drawings, in which:

FIG. 1 is a view illustrating schematically conventional monitoring device;

FIG. 2 is a view illustrating position of a monitoring device according to one embodiment of the present disclosure;

FIG. 3 is a view illustrating a decomposed structure of the monitoring device according to one embodiment of the present disclosure;

FIG. 4 and FIG. 5 are views illustrating arrangement of the monitoring device according to one embodiment of the present disclosure;

FIG. 6 is a view illustrating a guide member and a circuit board according to one embodiment of the present disclosure;

FIG. 7 is a view illustrating combination of elements in the monitoring device according to one embodiment of the present disclosure;

FIG. 8 is a view illustrating arrangement of electrical elements according to one embodiment of the present disclosure;

FIG. 9 is a view illustrating a part of a monitoring device according to another embodiment of the present disclosure;

FIG. 10 is a view illustrating decomposed structure of a monitoring device according to another embodiment of the present disclosure; and

FIG. 11 is a view illustrating arrangement of a guide member and a circuit module according to one embodiment of the present disclosure.

### DETAILED DESCRIPTION

In the present specification, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The present disclosure relates to a monitoring device and the monitoring device may check abnormalities of an object to be measured, e.g. an electrostatic chuck by measuring temperature distribution of the object in for example a semiconductor process or a display process. For example, the monitoring device may measure a RF voltage, current or a power in the semiconductor process or the display process in a plasma atmosphere. Additionally, the monitoring device may diagnose abnormalities of the electrostatic chuck by measuring a DC voltage of the electrostatic chuck.

For another example, the monitoring device may check a slope of the electrostatic chuck or a shower head by measuring a distance from the monitoring device to an upper electrode or a lower electrode.

The monitoring device may measure vibration generated from the electrostatic chuck or a semiconductor equipment.

In one embodiment, the monitoring device of the present embodiment may have a thickness less than a preset value to transfer and return automatically a wafer using a robot and measure also a wide area. Specifically, the monitoring device may measure characteristics of an edge area of the object corresponding to an extreme edge area of the wafer to be used in following process.

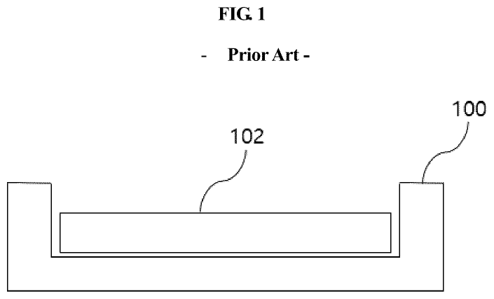

In a conventional wafer type monitoring device in FIG. 1, electrical elements 102 such as a sensor, etc. are disposed in an internal space of a wafer 100 of which a center is digged, and it is impossible to array the sensor on an area corresponding to a side part of the wafer 100 by the side part. As a result, the monitoring device may not measure temperature, etc. of an area corresponding to an edge area of the wafer 100 of the electrostatic chuck, the edge area of the wafer meaning an area within 3 mm from an edge of the wafer.

The monitoring device of the present disclosure may not have the structure that a center is digged, but a cover of the monitoring device may have a plane shape and a sensor may locate on an edge area of the cover, e.g. an area within 3 mm from an edge of the cover. As a result, the monitoring device may sense an edge area of the electrostatic chuck, and thus a sensing area may be widened.

A heater locates in the edge area of the electrostatic chuck, and heating or a cooling is applied to a wafer to be used in an etching process or a deposition process, etc. by the heater. This is, the heater in the edge area of the electrostatic chuck affects to the wafer. Accordingly, it is necessary to measure temperature, etc. of the edge area of the electrostatic chuck, but the conventional monitoring device may not measure the temperature, etc. of the edge area. To solve the problem, the monitoring device of the present disclosure has a structure enabling to measure characteristics of the edge area of the electrostatic chuck.

Hereinafter, various embodiments of the present disclosure will be described with reference to accompanying drawings. It is assumed that an object measured by the monitoring device is the electrostatic chuck for the purpose of convenience of description, but the object is not limited to the electrostatic chuck.

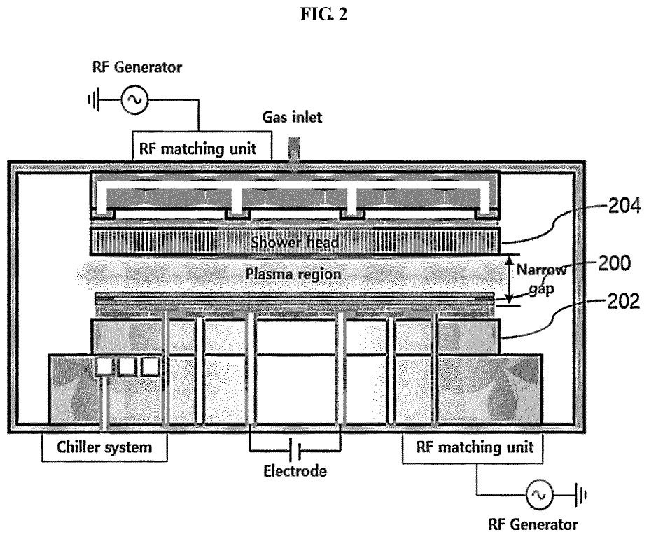

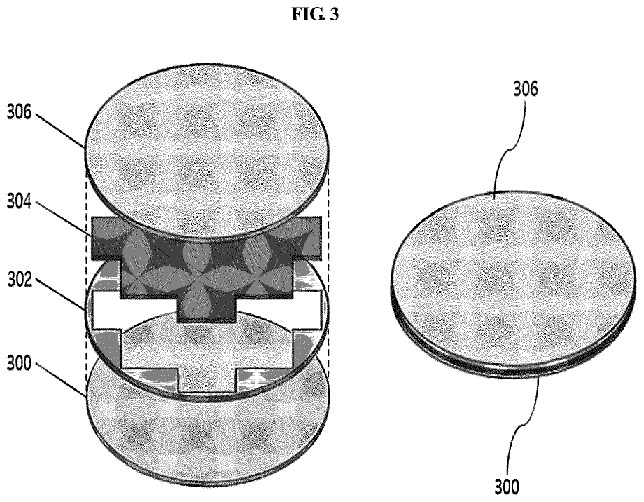

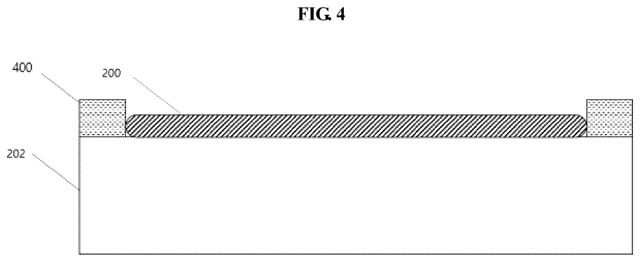

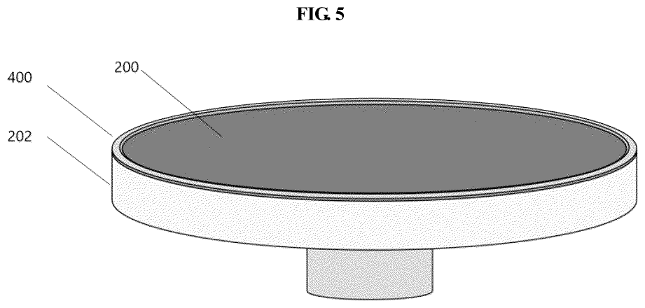

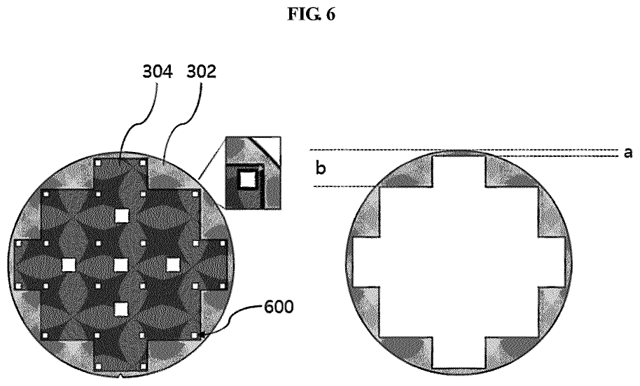

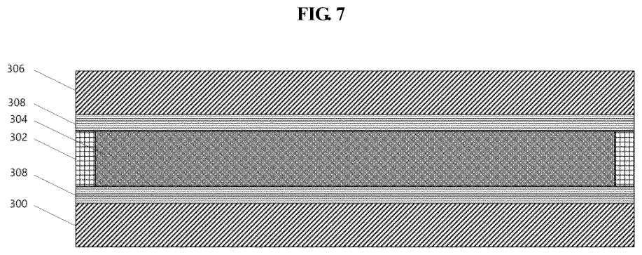

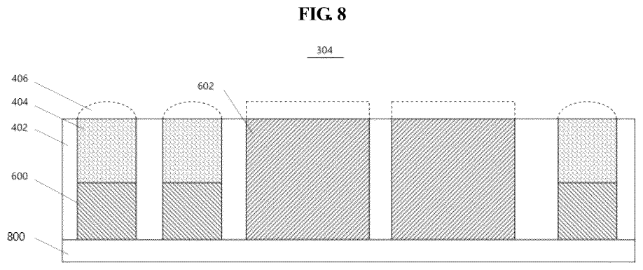

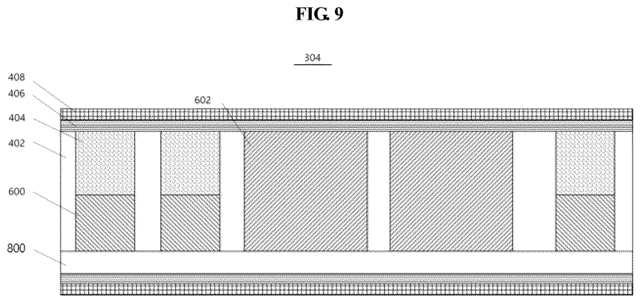

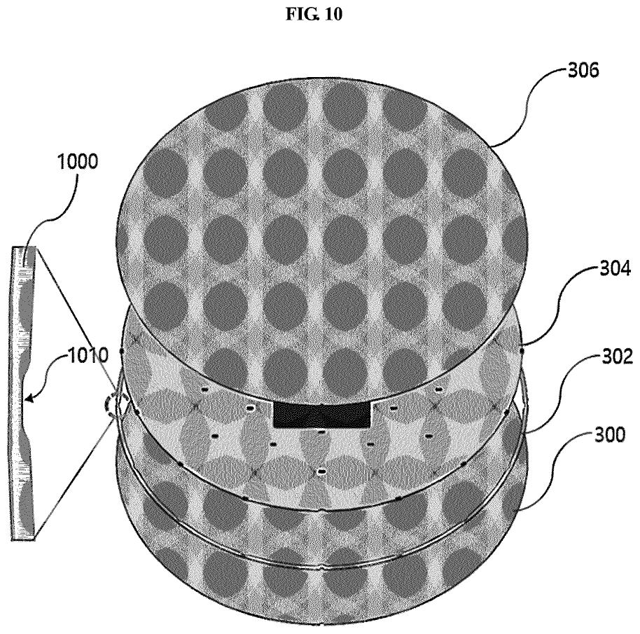

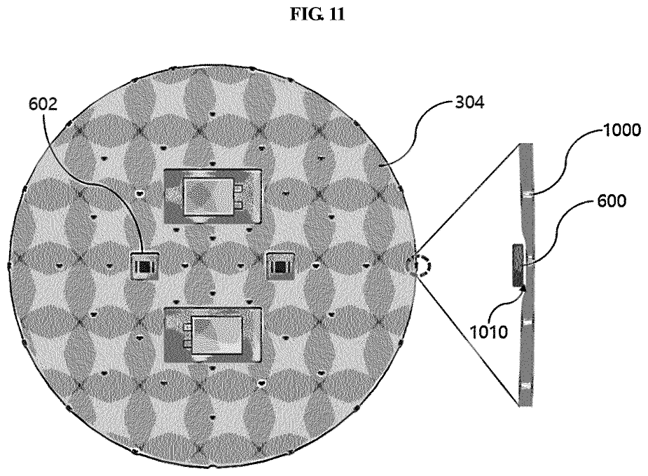

FIG. 2 is a view illustrating position of a monitoring device according to one embodiment of the present disclosure, FIG. 3 is a view illustrating a decomposed structure of the monitoring device according to one embodiment of the present disclosure, and FIG. 4 and FIG. 5 are views illustrating arrangement of the monitoring device according to one embodiment of the present disclosure. FIG. 6 is a view illustrating a guide member and a circuit board according to one embodiment of the present disclosure, FIG. 7 is a view illustrating combination of elements in the monitoring device according to one embodiment of the present disclosure, and FIG. 8 is a view illustrating arrangement of electrical elements according to one embodiment of the present disclosure. FIG. 9 is a view illustrating a part of a monitoring device according to another embodiment of the present disclosure, FIG. 10 is a view illustrating decomposed structure of a monitoring device according to another embodiment of the present disclosure, and FIG. 11 is a view illustrating arrangement of a guide member and a circuit module according to one embodiment of the present disclosure.

In FIG. 2, a monitoring device 200 of the present embodiment may locate on an electrostatic chuck 202 in a chamber in a contact type or non-contact type, and a shower head 204 may be disposed with separated from the monitoring device 200.

It is designed that a transfer path of a wafer is narrow in the chamber. That is, a space between the shower head 204 and the electrostatic chuck 202 is narrow to mange density or uniformity of plasma, and so it is preferable to design the monitoring device 200 to have a thickness less than a preset value.

In one embodiment, the monitoring device 200 of the present embodiment may design the monitoring device 200 to have the thickness less than the preset value by disposing electrical elements on a circuit module, filling a filler on an electrical element with low height and then polishing an upper surface of the filler on the electrical element.

The monitoring device 200 may check abnormalities of the electrostatic chuck 202 before a process starts and be removed from the electrostatic chuck 202 when it is determined that the electrostatic chuck 202 is normal, and then the process may be performed. For example, a wafer for a deposition process, an etching process or photography process may be laid on the electrostatic chuck 202 after the monitoring device 200 is removed.

The monitoring device 200 may locate on the electrostatic chuck 202 by using a robot without opening a chamber, and thus the chamber may keep a vacuum state.

In one embodiment, the monitoring device 200 may also measure temperature or a slope of the electrostatic chuck 202, a distance between an upper electrode and a lower electrode in a semiconductor equipment or a voltage and current or vibration of an equipment in a plasma atmosphere.

In one embodiment, the monitoring device 200 may locate inside an edge ring 400 on the electrostatic chuck 202 as shown in FIG. 4 and FIG. 5.

Referring to FIG. 3 to FIG. 8, the monitoring device 200 of the present embodiment may include a lower cover 300, a guide member 302, a circuit module 304 and an upper cover 306.

The lower cover 300 may protect the circuit module 304 and electrical elements on the circuit module 304 from external environment, e.g. a plasma environment and protect the chamber from pollutant generated from the circuit module 304.

In one embodiment, the lower cover 300 may have the same circular shape as a wafer as shown in FIG. 3, an upper surface and a lower surface of the lower cover 300 may have a plane shape, and the lower cover 300 may be formed of silicon or glass used frequently in a semiconductor process. In another embodiment, the lower cover 300 may be made up of silicon carbide, sapphire, Y₂O₃, YOF or Al₂O₃ which is ceramic material, or Teflon, PEEK or carbon fiber which is an engineering plastic.

The lower cover 300 contacts directly with the electrostatic chuck 202 which is an object to be measured, and thus the lower cover 300 may have the same flatness as a silicon wafer.

In one embodiment, the lower cover 300 may be adhered to the guide member 302 or the circuit module 304 by using an adhering layer 308 as shown in FIG. 7. Here, the adhering layer 308 may be an acrylic adhesive or a silicon adhesive. On the other hand, the lower cover 300 may be adhered to the guide member 302 or the circuit module 304 by using thermosetting material such as epoxy or an insulating material such as SOG or SOD.

The guide member 302 may protect a side part of the circuit module 304 from an external environment, e.g. plasma and enhance mechanical strength of the monitoring device 200. Additionally, common section of the upper cover 306, the guide member 302 and the lower cover 300 may cool the circuit module 304 from a heat source. To perform this function, the upper cover 306, the guide member 302 and the lower cover 300 may have the same conductivity as silicon or similar conductivity to the silicon.

In one embodiment, the guide member 302 is disposed on the lower cover 300 and a space in which the circuit module 304 is inserted may be formed to the guide member 302. That is, the circuit module 304 may be inserted into the space of the guide member 302 to be fixed. In another aspect, the guide member 302 may cover the circuit module 304.

The guide member 302 may be formed of the same material as the silicon wafer. In another embodiment, the guide member 302 may be made up of silicon carbide, sapphire, Y₂O₃, YOF or Al₂O₃ which is ceramic material, or Teflon, PEEK or carbon fiber which is an engineering plastic.

In one embodiment, the guide member 302 may have the same size and shape as the wafer or similar size and shape to the wafer, and one of distances from an edge of the guide member 302 to the space may have different value as shown in FIG. 6. For example, a distance from the edge of the guide member 302 to a first part of the space may be a, and a distance from the edge of the guide member 302 to a second part of the space may be b higher than a. If every distance from the edge of the guide member 302 to the space is a, the guide member 302 may be broken down and the strength of the monitoring device 200 may not be reinforced because the guide member 302 becomes thinner. Accordingly, a distance from the edge of the guide member 302 to the other part of the space may be designed to have a depending on location of a sensor 600, while a distance from the edge of the guide member 302 to a part of the space is b or more.

If the distance from the edge of the guide member 302 to the space is a, corresponding part of the circuit module 304 may close to the edge of the guide member 302 as shown in FIG. 6. Temperature, etc. of an area of the electrostatic chuck corresponding to an edge area of the wafer may be measured when the sensor 600 locates on the corresponding part of the circuit module 304. For example, at least partial of the sensor 600 may be disposed on an area between a part at which the distance to the space is a and a part at which the distance to the space is b, of the circuit module 304.

In one embodiment, the distance from the edge of the guide member 302 to the space may be a length within 1.5 mm to 3 mm from an edge of the wafer, an area within 1.5 mm to 3 mm from the edge of the wafer corresponding to an extreme edge of the wafer. Of course, this length depends on a size of the wafer, but the distance from the edge of the guide member 302 to the space may correspond to the extreme edge area of the wafer to be used in following process.

In another aspect, location of the sensor on the circuit module 304 may correspond to the extreme edge area of the wafer. The other part of the guide member 302 may reinforce mechanical strength of the guide member 302 of which strength become weaker according as partial of the guide member 302 is processed up to the extreme edge area.

In one embodiment, the space of the guide member 302 and the circuit module 304 may have a structure that relatively small quadrangles are connected to all sides of relatively great quadrangle, respectively. Of course, the space and the circuit module 304 may have different shape, e.g. circular shape. That is, the space and the circuit module 304 may have various shapes as long as the sensor locates on a position corresponding to the extreme edge area of the wafer.

In another embodiment, one of distances from an edge of the guide member 302 to the circuit module 304 may have different value. For example, a distance from the edge of the guide member 302 to a first part of the circuit module 304 may be c, and a distance from the edge of the guide member 302 to a second part of the circuit module 304 may be d larger than c.

In still another embodiment, the circuit module 304 may have the same a circular shape or an oval shape as the wafer or a circular shape or an oval shape similar to the wafer, and the guide member 302 may include a side member for protecting a side of the circuit module 304 and projection members 1000 crossing over the side member, e.g. vertical to the side member. The projection members 1000 may be separated, the circuit module 304 may have the same a circular shape or an oval shape as the wafer or a circular shape or an oval shape similar to the wafer, and the projection members 1000 may cover partial of an upper surface of the circuit module 304. Here, the sensor for sensing an edge of the object to be measured may be disposed in a space between the projection members 1000 of the circuit module 304, and electrical elements such as a microprocessor, etc. may locate outside of the projection members 1000 of the circuit module 304. In another viewpoint, the guide member 302 may cover an edge of the circuit module 304, wherein a home 1010 may be formed at the guide member 302, and at least partial of the sensor for sensing the edge may locate in the home 1010.

The circuit module 304 may be disposed in the internal space of the guide member 302 on the lower cover 300.

In the circuit module 304, electrical elements 602 such as the microprocessor, a wireless communication device, a wireless charger or sensors may be disposed on a circuit board 800. Specially, a part of the sensors may be disposed on an area corresponding to the extreme edge area of the wafer of the circuit board 800.

In one embodiment, the circuit board 800 is vulnerable to a stress because the circuit board 800 has a thickness less than a preset value as shown in FIG. 8. To reinforce the circuit board 800, a fixing cover 402 may be disposed on an area except the electrical elements 602 on the circuit board 800 to enhance flatness of the circuit board 800 and prevent bending of the circuit board 800. The fixing cover 402 may be formed of the same material as the upper cover 306 or the lower cover 300 or material similar to the upper cover 306 or the lower cover 300, for example epoxy, silicon, silicon carbide, glass, etc. Here, empty space for leads of the electrical elements, a soldering pad, etc. is generated after the fixing cover 402 is disposed on the circuit board 800. In this case, the empty space may be filled with the filler 404, and the filler 404 may be liquefied material such as epoxy, thermosetting resin, ceramic resin, etc. to improve the flatness of the circuit module 304.

In one embodiment, the circuit module 304 may include a basic substrate to which electrical wire is connected and a filling substrate for protecting the electrical elements and enhancing flatness. Here, the basic substrate and the filling substrate may be adhered by using an acrylic adhesive or a silicon adhesive.

In one embodiment, at least one of the electrical elements may have different height. Hence, every electrical element may have the same height by filling a filler 404 on electrical elements with relatively low height. It is because it is difficult to adhere the circuit module 304 to the upper cover 306 in the event that the heights of the electrical elements differ.

For example, the sensor 600 may have relatively low height compared to the microprocessor as shown in FIG. 8. In this case, the filler 404 may be filled on the sensor 600 so that the height of the sensor 600 filled with the filler 404 is identical to that of the microprocessor. Here, heights of tops of the electrical elements may be identical to height of a top of the guide member 302.

In one embodiment, the filler 404 may be a nonconductor, e.g. epoxy, silicon, thermosetting resin or ceramic resin.

In one embodiment, a top side of the circuit module 304 may have constant height by filling the filler 404 on a part of electrical elements and then polishing the tops of the electrical elements. That is, a part of the filler 404 greater than the constant height may be removed so that the top side of the circuit module 304 has constant height, the removed part being referred to as a polished layer 406. A surface of a part of the electrical elements may be also polished in a polishing process depending on a situation.

In one embodiment, the circuit module 304 may include the circuit board 800 on which electrical wires are connected and the fixing cover 402 for protecting the electrical elements and improving flatness of the circuit module 304. Here, the circuit board 800 and the fixing cover 402 may be adhered by using an acrylic adhesive or a silicon adhesive.

In one embodiment, as shown in FIG. 9, a first EMI shielding layer 406 for shielding electromagnetic wave may be formed on the guide member 302 and the electrical elements, and a second EMI shielding layer may be formed below the circuit module 304. Here, the shielding layers may be formed by coating liquefied material or in a film type. Furthermore, the shielding layers may be formed with gold, silver, copper, aluminum or their mixed material.

In another embodiment, the EMI shielding layer may be formed on the lower cover 300 and the upper cover 306.

In one embodiment, a heat blocking layer 408 for protecting the electrical elements from thermal shock by downing heat conductivity from a heat source to the circuit module 304 may be further formed below or on the circuit module 304 as shown in FIG. 9. The heat blocking layer 408 may include aerogel with low heat conductivity, be formed of liquefied material or in a film type.

The upper cover 306 may be adhered to the guide member 302 or the circuit module 304 through an adhering layer 308 and protect elements.

The adhering layer 308 may be an acrylic adhesive or a silicon adhesive. On the other hand, the upper cover 306 may be adhered to the guide member 302 or the circuit module 304 by using thermosetting material such as epoxy or an insulating material such as SOG or SOD.

On the other hand, the adhering layer 308 between the lower cover 300 and the guide member 302 or the circuit module 304 may be formed of the same material as the adhering layer 308 between the upper cover 306 and the guide member 302 or the circuit module 304, but the adhering layers may be formed of different material.

Briefly, in the monitoring device 200 of the present embodiment, at least partial of the circuit module 304 may be disposed in the space of the guide member 302, and the sensors may locate from an area corresponding to a central area of the wafer to an area corresponding to the extreme edge area of the wafer. As a result, the monitoring device 200 may measure characteristics of the edge area of the electrostatic chuck 202 for providing heat to the edge area of the wafer.

In the above, the monitoring device 200 measures abnormalities of the electrostatic chuck 202. However, the monitoring device 200 may be used for measuring RF voltage, RF current, RF power or a slope of a chuck or a shower head in an etching process, temperature of a high temperature chuck, RF voltage, RF current, RF power or a slope of a chuck or a shower head in a deposition process, temperature, a slope or vibration of a baking chuck in a photography process, or temperature, a slope or vibration of a chuck used in an implant apparatus. In the event that the chuck has high or low temperature, the monitoring device 200 may measure characteristics of the chuck with be directly contacted with the chuck or in a long distance.

Moreover, the monitoring device 200 may be used for measuring temperature, vibration or a slope of a photo mask used in an exposure process. Here, the monitoring device 200 may have the same structure as the monitoring device 200 described in above.

In another embodiment, the monitoring device 200 may not be physically contacted with the electrostatic chuck 202. The monitoring device 200 may monitor temperature of a high temperature chuck without being contacted with the high temperature chuck while it locates on a lift pin of the high temperature chuck, to diagnose the high temperature chuck in the deposition process.

Additionally, the monitoring device 200 may include an optical sensor for sensing a light or an electrical sensor for measuring electrical factor to monitor the object to be measured. In this case, to use the optical sensor, the monitoring device 200 may have the structure described in above, but the monitoring device 200 may further include a light receiving sensor for receiving a light and hole through which the light passes may be formed on the monitoring device 200.

Furthermore, to use the electrical sensor, the monitoring device 200 includes the electrical sensor, wherein hole through which an electrical signal passes may be formed on the monitoring device 200.

Moreover, the monitoring device 200 includes a displacement sensor for measuring a slope, wherein hole through which electrical signal or optical signal passes may be formed on the monitoring device 200.

Components in the embodiments described above can be easily understood from the perspective of processes. That is, each component can also be understood as an individual process. Likewise, processes in the embodiments described above can be easily understood from the perspective of components.

The embodiments of the invention described above are disclosed only for illustrative purposes. A person having ordinary skill in the art would be able to make various modifications, alterations, and additions without departing from the spirit and scope of the invention, but it is to be appreciated that such modifications, alterations, and additions are encompassed by the scope of claims set forth below.

1. A monitoring device comprising:
a lower cover;
a guide member disposed on the lower cover;
a circuit module in which at least one electrical element is disposed on a circuit board; and
an upper cover disposed on the guide member or the circuit module,
wherein a space is formed at the guide member, and at least partial of the circuit module locates in the space.

2. The monitoring device of claim 1, wherein a first distance from an edge of the guide member to a position of the space is different from a second distance from the edge to another position of the space,
and wherein the first distance is smaller than the second distance,
at least one of sensors which are one of electrical elements locates in an area between a part corresponding to the position of the space of the circuit module and a part corresponding to the another position of the space of the circuit module, to measure an edge area of an object to be measured.

3. The monitoring device of claim 2, wherein the monitoring device is disposed on an electrostatic chuck,
and wherein the monitoring device is removed after measuring characteristics of the electrostatic chuck, a wafer for following process is laid on the electrostatic chuck after the monitoring device is removed, and
a sensor locates on an area corresponding to an extreme edge area of the wafer of the circuit module.

4. The monitoring device of claim 1, wherein each of the lower cover and the upper cover has a plane shape, and the space or the circuit module has a structure in which shapes with relatively small size are connected to a shape with relatively great size,
and wherein a sensor is disposed on the shape with relatively small size.

5. The monitoring device of claim 1, wherein a first element with relatively small height and a second element with relatively great height are disposed on the circuit module,
and wherein a filler is filled on the first element and a top of the filler filled on the first element is polished, thereby making the first element on which the filler is filled to have the same height as the second element, and
the first element on which the filler is filled, the second element and the guide member have the same height.

6. The monitoring device of claim 5, wherein a first EMI shielding layer is formed on the first element on which the filler is filled and the second element, and a second EMI shielding layer is formed below the circuit module.

7. The monitoring device of claim 1, wherein EMI shielding layers for shielding electromagnetic wave are formed on the upper cover and the lower cover, respectively.

8. The monitoring device of claim 1, wherein the lower cover, the guide member or the upper cover is formed of the same material as a silicon wafer, silicon carbide, sapphire, Y₂O₃, YOF or Al₂O₃ which is ceramic material, or Teflon, PEEK or carbon fiber which is an engineering plastic.

9. The monitoring device of claim 1, wherein the circuit module includes the circuit board, electrical elements disposed on the circuit board and a fixing cover disposed on an area except an area on which the electrical elements are disposed, on the circuit board, and the fixing cover is formed of epoxy, silicon, silicon carbide or glass.

10. The monitoring device of claim 1, wherein the guide member and the circuit board have respectively a circular shape or an elliptic shape, and the guide member includes a side member for protecting a side part of the circuit module and projection members which are vertical to the side member and cover a part of an upper surface of the circuit module,
and wherein the projection members are separated, a sensor for sensing an object to be measured is disposed between the projection members of the circuit module, electrical elements except the sensor are disposed outside the projection member of the circuit module.

11. A monitoring device comprising:
a lower cover;
a circuit module disposed on the lower cover;
elements disposed on the circuit module; and
an upper cover disposed on the elements,
wherein the elements include a first element with relatively low height and a second element with relatively great height,
a filler is filled on the first element, and a height of the first element on which the filler is filled is identical to a height of the second element.

12. The monitoring device of claim 11, wherein a heat blocking layer is formed below the circuit module to protect the elements from thermal shock.

13. The monitoring device of claim 11, wherein the elements include at least one electrical element disposed on the circuit module; and
wherein a sensor as the electrical element is disposed on an area of the circuit module corresponding to an extreme edge area of a wafer.

14. A method of manufacturing a monitoring device, the method comprising:
disposing a circuit board on a lower cover;
forming a first element with relatively low height and a second element with relatively great height on the circuit board;
filling a filler on the first element, thereby making the first element on which the filler is filled to have the same height as the second element; and
disposing an upper cover on the first element and the second element.

15. The method of claim 14, further comprising:
forming a guide member to cover the circuit board,
wherein the filler is filled on the first element and then the filler on the first element is polished so that the first element on which the filler is filled, the second element and the guide member have the same height.
